(19) United States
(12) Patent Application Publication
(10) Pub. No.: US 2026/0362611 A1
(43) Pub. Date: Nov. 12, 2026

(54) ELECTRONIC CIRCUIT UNIT

(71) Applicant: HARADA INDUSTRY CO., LTD., Tokyo (JP)

(72) Inventor: Isao HOSHINO, Shinagawa-ku, Tokyo (JP)

(21) Appl. No.: 18/996,986

(22) PCT Filed: Mar. 18, 2024
(86) PCT No.: PCT/JP2024/010447

§ 371 Date: Jan. 18, 2025

(30) Foreign Application Priority Data
Mar. 30, 2023 (JP) 2023-056672

(51) Int. Cl. H05K 5/00; F16B 41/00

(52) U.S. Cl. CPC H05K 5/0069; F16B 41/002

(57) ABSTRACT

An electronic circuit unit includes a washer assembled screw, a circuit board, a case, a screw coming-off preventing rib, and a base plate. The case covering the circuit board has a counterbore with a diameter larger than a diameter of a screw head of the washer assembled screw and a depth larger than the height of the screw head. The screw coming-off preventing rib has an inner diameter smaller than a diameter of a washer of the washer assembled screw and larger than the diameter of the screw head, and is disposed at such a height that the washer assembled screw stops at a position at which the screw tip of the washer assembled screw does not escape from a through hole of the circuit board. The base plate has a female screw with which the washer assembled screw is engaged.

### CROSS-REFERENCE TO RELATED APPLICATIONS

This application is a U.S. national stage application of International Application No. PCT/JP2024/010447, filed on Mar. 18, 2024. This application claims priority to Japanese Patent Application No. 2023-056672, filed on Mar. 30, 2023.

### BACKGROUND

### Technical Field

The present invention relates to an electronic circuit unit having an electronic circuit, and more particularly to an electronic circuit unit having a screw coming-off preventing structure.

### Background Information

A glass antenna installed on a front glass or a rear glass is known as one of vehicle antennas. Specifically, the glass antenna has a structure in which a conductive wire serving as an antenna element is provided in the form of a seal and attached to the glass or embedded in the glass. The glass antenna has a terminal serving as a feed point, which is connected with a coaxial cable from a radio receiver or the like. There are various types of connectors for such connection. For example, there is known an electronic circuit unit such as an amplifier holder having a structure in which an electronic circuit such as an amplifier circuit is incorporated in a connector. The electronic circuit unit of such a type is fixed facing the glass by means of a double-sided tape.

Such an electronic circuit unit is configured to be removable from the glass so as to be replaceable for the failure etc. of the amplifier circuit therein. For example, Patent Document 1 discloses a circuit module having a structure in which a module main body thereof accommodating a circuit board in a chassis is fixed, by a screw, to a base plate to be joined to glass. When the circuit board needs to be replaced, the screw is removed after removal of a case locked to the chassis, thus allowing easy detachment of the circuit board from the base plate.

However, when an electronic circuit unit having a configuration completely covered with the case, like one disclosed in Japanese Laid-Open Patent Application No. 2008-263537A (hereinafter referred to as Patent Document 1), it is necessary to remove the case from the chassis in a state where the electronic circuit unit is fixed to the glass, thus being poor in workability. To cope with this, in in Japanese Laid-Open Patent Application No. 2009-044334A (hereinafter referred to as Patent Document 2), a screw member operation hole having a diameter smaller than the diameter of a screw head and larger than the diameter of the tip of a driver engaged with the screw head is formed in the case so as to allow rotation of the screw in a state where the case is fixed to the circuit board. In Patent Document 2, the screw member operation hole has a diameter smaller than the diameter of the screw head, so that coming-off of the screw is prevented, thereby improving workability at screwing. Further, the screw member operation hole has a thin wall portion configured to be broken so that the screw can be completely separated from the base plate.

### SUMMARY

However, the screw member operation hole described in Patent Document 2 has a diameter smaller than the diameter of the screw head and larger than the diameter of the tip of the driver engaged with the screw head, so that there is a restriction on the tip of the driver to be used. In other words, only a driver having a relatively thin tip end can be used. Further, in order to separate the screw from the base plate, it is necessary to break the case.

Therefore, there is desired an electronic circuit unit allowing easy removal of a screw therefrom when needed while preventing unintended coming-off of the screw, free from restriction on the diameter of the tip of a driver to be used, and allowing reuse of the case thereof.

The present invention has been made in view of the above situation, and an object thereof is to provide an electronic circuit unit capable of preventing coming-off of a screw for fastening the circuit board and the base plate, free from restriction on the diameter of the tip of a driver to be used, and allowing replacement of the circuit board without breakage of the case.

To achieve the above object of the present invention, an electronic circuit unit according to the present invention, includes: a washer assembled screw having a screw head and a screw shaft and assembled with a washer; a circuit board having a through hole through which the screw shaft of the washer assembled screw penetrates and mounted with an electronic circuit; a case covering the circuit board and having a counterbore with a diameter larger than a diameter of the screw head of the washer assembled screw and a depth larger than the height of the screw head; a screw coming-off preventing rib positioned inside the counterbore formed in the case, having an inner diameter smaller than a diameter of the washer of the washer assembled screw and larger than the diameter of the screw head, and disposed at such a height that the washer assembled screw stops at a position at which the screw tip of the washer assembled screw does not escape from the through hole of the circuit board; and a base plate fitted to the case to define the internal space and having a female screw with which the washer assembled screw is engaged for detachably fixing the circuit board to the base plate.

The screw coming-off preventing rib may be disposed in such a height that the screw tip of the washer assembled screw can be moved to a position not reaching the female screw when the base plate is fitted to the case.

The screw coming-off preventing rib may be disposed at such a height that the washer assembled screw stops at a position at which the screw tip of the washer assembled screw stays within the thickness of the through hole of the circuit board.

The case may have a reinforcing frame fixed thereinside, and the reinforcing frame is fixed to the circuit board.

The reinforcing frame may have a frame through hole with an inner diameter smaller than the diameter of the washer of the washer assembled screw and larger than the diameter of the screw head, and the frame through hole functions as the screw coming-off preventing rib.

The screw coming-off preventing rib may be disposed on an inner side wall of the counterbore of the case.

The electronic circuit unit may be an amplifier holder attached facing an electrode of a glass antenna, and the female screw of the base plate is a female screw with a spring terminal which contacts the electrode of the glass antenna to be electrically connected thereto.

### Advantageous Defects of The Invention

The electronic circuit unit according to the present invention is advantageous in that it is capable of preventing coming-off of a screw for fastening the circuit board and the base plate, free from restriction on the diameter of the tip of a driver to be used, and allowing replacement of the circuit board without breakage of the case.

### BRIEF DESCRIPTION OF THE DRAWINGS

Referring now to the attached drawings which form a part of this original disclosure, illustrative embodiments are shown.

FIG. 1 is a schematic perspective view for explaining the entire configuration of an electronic circuit unit according to the present invention.

FIG. 2A is a schematic partial cross-sectional side view of the electronic circuit unit showing a state before screw fastening.

FIG. 2B is a schematic partial cross-sectional side view of the electronic circuit unit showing a state after screw fastening when the electronic circuit unit is assembled.

FIG. 3 is a schematic perspective view for explaining the entire configuration of another example of the electronic circuit unit according to the present invention.

FIG. 4A is a schematic partial cross-sectional side view of the electronic circuit unit showing a state before screw fastening and for explaining an example in which a screw coming-off preventing rib is provided to a reinforcing frame of the electronic circuit unit.

FIG. 4B is a schematic partial cross-sectional side view of the electronic circuit unit showing a state after screw fastening when the electronic circuit unit is assembled.

### DETAILED DESCRIPTION OF EMBODIMENTS

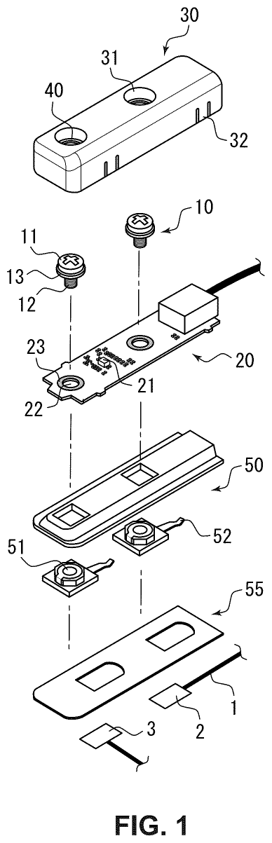

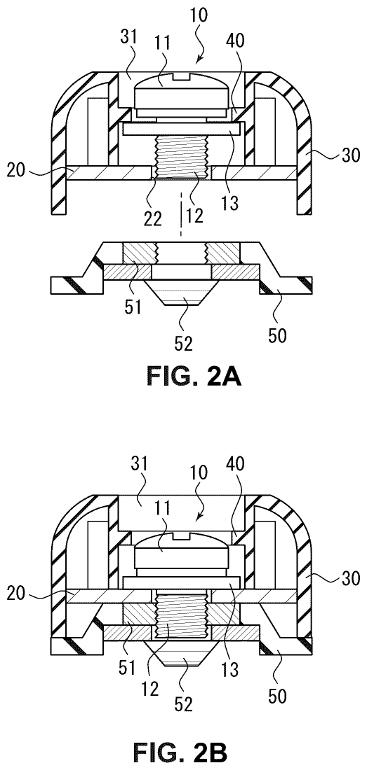

Hereinafter, an embodiment for practicing the present invention will be described with illustrated examples. FIG. 1 is a schematic perspective view for explaining the entire configuration of an electronic circuit unit according to the present invention. FIGS. 2A and 2B are schematic partial cross-sectional side views for explaining states before and after screw fastening when the electronic circuit unit according to the present invention is assembled. FIG. 2A illustrates a state before screw fastening, and FIG. 2B illustrates a state after screw fastening. In the drawing, the same reference numerals as those in FIG. 1 denote the same parts. The following describes an example in which the electronic circuit unit is used as an amplifier holder attached facing electrodes 2 and 3 of a glass antenna 1. However, the present invention is not limited to this and may be applied to any type of electronic circuit unit as long as it has a screw coming-off preventing structure.

As illustrated in FIGS. 1, 2A and 2B, the electronic circuit unit according to the present invention mainly includes a washer assembled screw 10, a circuit board 20, a case 30, a screw coming-off preventing rib 40, and a base plate 50.

The washer assembled screw 10 has a screw head 11 and a screw shaft 12 and assembled with a washer 13. More specifically, the washer 13 has a diameter larger than the diameter of the screw head 11. The washer 13 may be a flat washer or a spring washer. Alternatively, the washer 13 may be formed by combining the flat washer and the spring washer. The washer assembled screw 10 may appropriately be selected from having the length of the screw shaft 12 in which the screw tip of the washer assembled screw 10 does not penetrate through the base plate 50 in a state where the case 30 described later is fitted to the base plate 50 and fastened to the base plate 50 by the washer assembled screw 10. That is, it may have such a length that the screw tip of the washer assembled screw 10 does not protrude from the back surface of the base plate 50. Although two washer assembled screws 10 are used in the illustrated example, the number of the washer assembled screws 10 to be used in the electronic circuit unit is not particularly limited in the present invention.

The circuit board 20 is a board on which an electronic circuit 21 is mounted. The electronic circuit 21 is an amplifier circuit or a filter circuit, for example. Further, the circuit board 20 has a through hole 22 through which the screw shaft 12 of the washer assembled screw 10 penetrates. That is, the through hole 22 is formed at a position at which the screw shaft 12 penetrates through the circuit board 20 when the washer assembled screw 10 is fastened. Further, when the washer assembled screw 10 is used to electrically connect the circuit board 20 and the electrodes 2 and 3 of the glass antenna 1, an annular conductive land 23 may be provided as needed so as to allow conduction between the washer assembled screw 10 and the electronic circuit 21 of the circuit board 20. Specifically, electricity passes from the annular conductive land 23 to the washer assembled screw 10 through the washer 13.

The case 30 covers the circuit board 20. The case 30 has a counterbore 31. The counterbore 31 has a diameter larger than the diameter of the screw head 11 of the washer assembled screw 10 and has a depth larger than the height of the screw head 11. Specifically, as illustrated in FIGS. 2A and 2B, the counterbore 31 may have such a depth as not to allow the screw head 11 to protrude from the case 30 after screw fastening. Further, the counterbore 31 may be formed so as to have a cylindrical side wall. That is, the counterbore 31 has a bottomless cylindrical shape. Since the counterbore 31 has a diameter larger than the diameter of the screw head 11, a driver to be engaged with the screw head 11 is not limited to a thin one, but a standard type can be used. Further, the case 30 may have a locking pawl 32 so as to be locked to the circuit board 20. By this locking pawl 32, the case 30 is fixed to the circuit board 20. The base plate 50 may also have a locking pawl. As illustrated in FIGS. 2A and 2B, the side wall of the counterbore 31 is configured such that the lower end portion thereof abuts with the circuit board 20. This can prevent dust and dirt from entering inside the case 30 through the counterbore 31.

The screw coming-off preventing rib 40 is provided for preventing the washer assembled screw 10 from coming off from the case 30. The screw coming-off preventing rib 40 is formed inside the counterbore 31. Specifically, as illustrated in FIGS. 2A and 2B, the screw coming-off preventing rib 40 is constituted by an inside annular rib structure formed on the inner side wall of the counterbore 31 of the case 30. The screw coming-off preventing rib 40 has an inner diameter smaller than the diameter of the washer 13 of the washer assembled screw 10 and larger than the diameter of the screw head 11. That is, the screw coming-off preventing rib 40 is configured by an annular rib having a through hole with such an inner diameter as to, when the washer assembled screw 10 is inserted from the lower portion in FIGS. 2A and 2B before the circuit board 20 is locked to the case 30, allow passage of the screw head 11 through the screw coming-off preventing rib 40 but not allow passage of the washer 13 therethrough. With this configuration, it is possible to prevent the washer assembled screw 10 from coming off from the case 30.

Further, the screw coming-off preventing rib 40 is disposed at such a height that the washer assembled screw 10 stops at a position at which the screw tip of the washer assembled screw 10 does not escape from the through hole 22 of the circuit board 20. That is, the positional relationship between the washer 13 and the screw coming-off preventing rib 40 may be adjusted so as to prevent the screw tip from escaping from the through hole 22 even in a state where the washer assembled screw 10 is disposed at the maximum height (in a state illustrated in FIG. 2A). Such construction can prevent to deteriorate workability in subsequent fastening work when the screw tip of the washer assembled screw 10 escapes from the through hole 22 and the washer assembled screw 10 is tilted inside the counterbore 31. In the illustrated example of FIG. 2B, the screw coming-off preventing rib 40 is disposed at such a height that the washer assembled screw 10 stops at a position at which the screw tip of the washer assembled screw 10 stays within the thickness of the through hole 22; however, the present invention is not limited to this, the screw coming-off preventing rib 40 may be disposed at such a height that the washer assembled screw 10 stops at a position at which the screw tip protrudes from the through hole 22 as long as the screw tip does not escape from the through hole 22.

The base plate 50 is fitted to the case 30 to define the internal space. That is, the base plate 50 is fitted to the lower opening of the case 30. The base plate 50 has a female screw 51. The female screw 51 is engaged with the washer assembled screw 10 so as to detachably fix the circuit board 20 to the base plate 50. In the illustrated example, the electronic circuit unit is configured as an amplifier holder for the glass antenna 1, and the female screw 51 is provided with a spring terminal 52 which contacts the electrodes 2 and 3 of the glass antenna 1 to be electrically connected thereto. The female screw 51 may be insert-molded in the base plate 50. The thus configured base plate 50 may be attached to the glass using a double-sided tape 55 or the like.

As described above, the positional relationship between the washer 13 and the screw coming-off preventing rib 40 is adjusted so as not to allow the screw tip to escape from the through hole 22. Further, the screw coming-off preventing rib 40 may be disposed as follows. That is, as illustrated in FIG. 2, the screw coming-off preventing rib 40 may be disposed at such a height that the screw tip of the washer assembled screw 10 can be moved to a position not reaching the female screw 51 when the base plate 50 is fitted to the case 30. Specifically, the screw coming-off preventing rib 40 is disposed at a position allowing the washer assembled screw 10 to be lifted to a position where the screw tip of the washer assembled screw 10 does not reach the female screw 51 in a state before the washer assembled screw 10 is screwed into the female screw 51 (i.e., in a state illustrated in FIG. 2A). That is, the position at which the screw tip does not escape from the through hole 22 and at which the screw tip does not reach the female screw 51 refers to the position withing the thickness of the through hole 22 of the circuit board 20. Therefore, the screw coming-off preventing rib 40 may be disposed at such a height that the washer assembled screw 10 stops at a position at which the screw tip of the washer assembled screw 10 stays within the thickness of the through hole 22 of the circuit board 20. When the screw tip of the washer assembled screw 10 protrudes to a position reaching the female screw 51 at fitting of the base plate 50 to the case 30, fitting therebetween may be hindered; on the other hand, when the washer assembled screw 10 is lifted to a position at which the screw tip does not reach the female screw 51, the washer assembled screw 10 can be engaged with the female screw 51 after fitting of the base plate 50 to the case 30. This further improves workability at assembly.

The thus configured electronic circuit unit according to the present invention may be assembled as follows. The base plate 50 is assembled with the female screw 51 and is then attached to the glass using the double-sided tape 55. The washer assembled screw 10 is made to penetrate through the through hole 22 of the circuit board 20, and the resultant circuit board 20 is covered with case 30. When the circuit board 20 is locked to the case 30, it is not possible for the washer assembled screw 10 to escape from the counterbore 31. Further, it is not possible for the screw tip to escape from the through hole 22. In this state, the case 30 is fitted to the base plate 50. Then, the washer assembled screw 10 is fastened to fix the circuit board 20 to the base plate 50.

When the electronic circuit unit needs to be replaced, the washer assembled screw 10 is loosened, thereby allowing the circuit board 20 to be easily removed from the base plate 50 together with the case 30. When the reason for the replacement is a failure of the circuit board 20, only the circuit board 20 needs to be replaced with new one, and the case 30 and the washer assembled screw 10 are reusable.

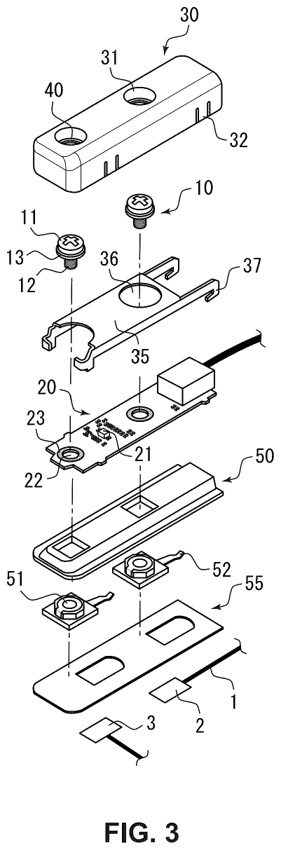

The following describes another example of the electronic circuit unit according to the present invention using FIG. 3. FIG. 3 is a schematic perspective view for explaining the entire configuration of another example of the electronic circuit unit according to the present invention. In the drawing, the same reference numerals as those in FIG. 1 denote the same parts. A difference from FIG. 1 is that a reinforcing frame 35 for reinforcing the case 30 is additionally provided. The reinforcing frame 35 may be fixed inside the case 30. That is, the locking pawl 32 of the case 30 may be locked to the reinforcing frame 35. When the reinforcing frame 35 is disposed at a position where the washer assembled screw 10 passes as illustrated, a frame through hole 36 may be formed in the reinforcing frame 35. The reinforcing frame 35 may be fixed to the circuit board 20 as needed. The reinforcing frame 35 may be fixed to the circuit board 20 using a screw or the like or may be fixed thereto by pinching the circuit board 20 with a locking part 37 as illustrated. For enhancing strength, the thus configured reinforcing frame 35 may be used for the case 30.

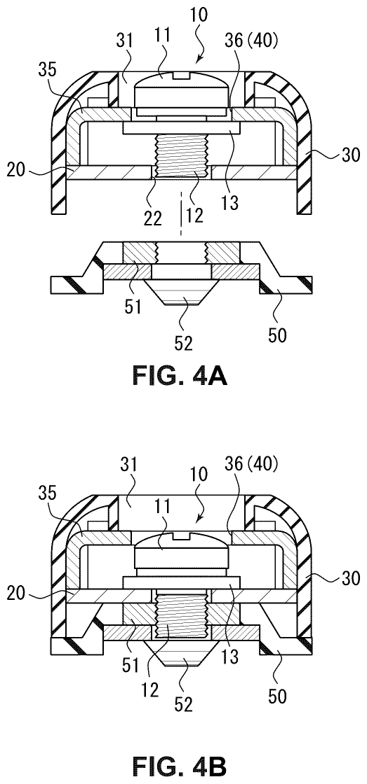

Further, as described below, the reinforcing frame 35 may be used to provide the screw coming-off preventing rib. FIGS. 4A and 4B are schematic partial cross-sectional side views for explaining an example in which the screw coming-off preventing rib is provided to the reinforcing frame of the electronic circuit unit according to the present invention. FIG. 4A illustrates a state before screw fastening, and FIG. 4B illustrates a state after screw fastening. In the drawing, the same reference numerals as those in FIG. 3 denote the same parts. In the example illustrated in FIG. 2, the screw coming-off preventing rib 40 is constituted by the inside annular rib structure formed on the inner side wall of the counterbore 31 of the case 30. On the other hand, in the example illustrated in FIGS. 4A and 4B, the frame through hole 36 is configured to function as the screw coming-off preventing rib 40. That is, the frame through hole 36 of the reinforcing frame 35 has an inner diameter smaller than the diameter of the washer 13 of the washer assembled screw 10 and larger than the diameter of the screw head 11. Therefore, as in the case of the above-described illustrated example, when the washer assembled screw 10 is inserted from the lower portion in FIGS. 4A and 4B, the screw head 11 can pass through the frame through hole 36 functioning as the screw coming-off preventing rib, but the washer 13 cannot pass through the frame through hole 36. This can prevent the washer assembled screw 10 from coming off from the case 30.

Further, as in the case of the above example, the frame through hole 36 may be disposed at such a height that the washer assembled screw 10 stops at a position at which the screw tip of the washer assembled screw 10 does not escape from the through hole 22 of the circuit board 20, and the frame through hole 36 may be disposed at such a height that the screw tip of the washer assembled screw 10 can be moved to a position not reaching the female screw 51 when the base plate 50 is fitted to the case 30.

The assembly method for the electronic circuit unit illustrated in FIGS. 3, 4A and 4B is substantially the same as that for the electronic circuit unit illustrated in FIGS. 1 and 2. A difference from the electronic circuit unit illustrated in FIGS. 1 and 2 is that the washer assembled screw 10 is made to penetrate through the through hole 22 of the circuit board 20 at first, and the reinforcing frame 35 is locked to the resultant circuit board 20. In this state, the case 30 is fixed to the circuit board 20 through the reinforcing frame 35. In a state where the circuit board 20 is locked with the case 30, the washer assembled screw 10 is prevented from escaping from the counterbore 31. The screw tip is also prevented from escaping from the through hole 22. In this state, the case 30 is fitted to the base plate 50. Then, the washer assembled screw 10 is fastened to fix the circuit board 20 to the base plate 50.

When the electronic circuit unit needs to be replaced, the washer assembled screw 10 is loosened, thereby allowing the circuit board 20 to be easily removed from the base plate 50 together with the case 30 and the reinforcing frame 35.

As described above, the electronic circuit unit according to the present invention is capable of preventing coming-off of a screw for fastening the circuit board and the base plate, free from restriction on the diameter of the tip of a driver to be used, and allowing replacement of the circuit board without breakage of the case.

The electronic circuit unit according to the present invention is not limited to the above illustrated examples but may be variously modified without departing from the spirit of the present invention.

### REFERENCE SIGNS LIST

1: Glass antenna
2, 3: Electrode
10: Washer assembled screw
11: Screw head
12: Screw shaft
13: Washer
20: Circuit board
21: Electronic circuit
22: Through hole
23: Annular conductive land
30: Case
31: Counterbore
32: Locking pawl
35: Reinforcing frame
36: Frame through hole
37: Locking part
40: Screw coming-off preventing rib
50: Base plate
51: Female screw
52: Spring terminal
55: Double-sided tape

1. An electronic circuit unit comprising:
a washer assembled screw having a screw head and a screw shaft and assembled with a washer;
a circuit board having a through hole through which the screw shaft of the washer assembled screw penetrates and mounted with an electronic circuit;
a case covering the circuit board and having a counterbore with a diameter larger than a diameter of the screw head of the washer assembled screw and a depth larger than the height of the screw head;
a screw coming-off preventing rib positioned inside the counterbore formed in the case, having an inner diameter smaller than a diameter of the washer of the washer assembled screw and larger than the diameter of the screw head, and disposed at such a height that the washer assembled screw stops at a position at which the screw tip of the washer assembled screw does not escape from the through hole of the circuit board; and
a base plate fitted to the case to define the internal space and having a female screw with which the washer assembled screw is engaged for detachably fixing the circuit board to the base plate.

2. The electronic circuit unit according to claim 1, wherein
the screw coming-off preventing rib is disposed in such a height that the screw tip of the washer assembled screw can be moved to a position not reaching the female screw when the base plate is fitted to the case.

3. The electronic circuit unit according to claim 1, wherein
the screw coming-off preventing rib is disposed at such a height that the washer assembled screw stops at a position at which the screw tip of the washer assembled screw stays within the thickness of the through hole of the circuit board.

4. The electronic circuit unit according to claim 1, wherein
the case has a reinforcing frame fixed there inside, and the reinforcing frame is fixed to the circuit board.

5. The electronic circuit unit according to claim 4, wherein
the reinforcing frame has a frame through hole with an inner diameter smaller than the diameter of the washer of the washer assembled screw and larger than the diameter of the screw head, and the frame through hole functions as the screw coming-off preventing rib.

6. The electronic circuit unit according to claim 1, wherein
the screw coming-off preventing rib is disposed on an inner side wall of the counterbore of the case.

7. The electronic circuit unit according to claim 1, wherein
the electronic circuit unit is an amplifier holder attached facing an electrode of a glass antenna, and
the female screw of the base plate is a female screw with a spring terminal which contacts the electrode of the glass antenna to be electrically connected thereto.
